(19) United States
(12) Patent Application Publication
(10) Pub. No.: US 2013/0100571 A1
(43) Pub. Date: Apr. 25, 2013

(54) FULLY ISOLATED COAXIAL SURGE PROTECTOR

(71) Applicant: JOHN MEZZALINGUA ASSOCIATES, INC., East Syracuse, NY (US)

(72) Inventors: ERDOGAN ALKAN, Fayetteville, NY (US); NOAH MONTENA, Syracuse, NY (US)

(73) Assignee: JOHN MEZZALINGUA ASSOCIATES, INC., East Syracuse, NY (US)

(21) Appl. No.: 13/655,627

(22) Filed: Oct. 19, 2012

Related U.S. Application Data
(60) Provisional application No. 61/548,857, filed on Oct. 19, 2011.

(51) Int. Cl. H02H 9/04; H02H 9/00

(52) U.S. Cl. CPC H02H 9/044; H02H 9/005; H05K 13/00
USPC 361/118; 29/869

(57) ABSTRACT

A protective device for a coaxial cable system including a first interface pin and a second interface pin positioned in axial relationship along a longitudinal axis with the first interface pin such that a dielectric gap is formed between the first and second interface pins, the dielectric gap being configured to couple radio frequency signals across the dielectric gap and block low frequency electrical current across the dielectric gap. A housing positioned in an axially surrounding relation to the first interface pin and an outer conductor interface positioned in axial relationship to the housing such that a coupling gap is formed between outer conductor interface and the housing, the coupling gap configured to couple radio frequency signals across the coupling gap and block low frequency electrical current across the coupling gap.

### CROSS-REFERENCE TO RELATED APPLICATIONS

This application claims priority to U.S. Provisional Application Ser. No. 61/548,857, filed on Oct. 19, 2011.

### FIELD

This invention is directed generally to surge protectors and, more particularly, relates to a fully isolated coaxial surge protector for use in high frequency communications systems.

### BACKGROUND

Coaxial cable devices, such as coaxial cables and coaxial connectors, are widely used to transmit electromagnetic signals, such as radio frequency signals, between a source and a load. Coaxial cable devices are typically designed to transmit electromagnetic signals over 10 MHz with minimum loss and little or no distortion. As a result, coaxial cable devices are commonly used to transmit and receive signals used for broadcast, cellular phone, GSM, data and other uses.

A coaxial cable device comprises a center conductor coaxially spaced inside an outer conductor, with a dielectric material filling the space between the center conductor and the outer conductor. The center conductor transmits an electric current component of the electromagnetic signals, while the outer conductor acts as a return path, or ground, for the electric current. The outer conductor also acts as a shield to shield desired signals traveling within the coaxial cable device from external signals, and to prevent the signals traveling within the coaxial cable from leaking out. The dielectric material electrically insulates the center conductor from the outer conductor, and fills the space through which a radio frequency wave component of the electromagnetic signals travels.

Coaxial cable devices are designed and intended to communicate desirable signals, such as CATV signals in the range between 800 MHz and 1200 MHz. Yet undesirable electromagnetic signals which fall outside of the desired frequency band are sometimes transmitted through coaxial cable devices. For example, coaxial cable devices are susceptible to communicating naturally created, low frequency electromagnetic impulses of the type produced by lightning. As another example, coaxial cable devices are susceptible to communicating transient, large current, artificially created electromagnetic impulses of the type produced by motors, switches, and certain types of—electrical circuits. These naturally and artificially created signal surges often have large electrical currents, high voltages, and short durations.

Undesirable electromagnetic signals that pass through a coaxial cable device can damage or destroy the load which is connected to the coaxial cable device. For example, a high voltage surge, such as one caused by a lightning strike, in a coaxial cable line on a wireless base station tower can damage or destroy a sensitive and expensive receiver connected on that coaxial cable line, causing the loss of cellular telecommunication services. Passing undesirable signals, therefore, can be very problematic.

To address this potential problem, coaxial cable devices often include some type of protective device for eliminating or reducing the undesirable electromagnetic signals before the undesirable signals transmit to the load. Current protective devices divert the undesirable electrical current from the center conductor to the outer conductor, which disseminates the undesirable signals to ground. Spark gaps, quarter wave stubs, and gas discharge tubes are the effective components of these protective devices.

A protective device with a spark gap has a small gap of air or another gas between the center conductor and a conductive element which is in electrical communication with the outer conductor. When signals surge through the protective device, the higher voltage of the electrical current on the center conductor creates a greater potential difference between the center conductor and the conductive element which, in turn, ionizes the air, creating a conductive medium for the electrical current to bridge the small gap from the center conductor to the conductive element. The high voltage electrical current is then conducted to the outer conductor and to ground. The threshold voltage that triggers the spark can be adjusted by adjusting the gap distance.

A gas discharge tube is a version of a spark gap, except a gas discharge tube encloses the gas in a container to better control the type and conditions of the gas. A protective device with a gas discharge tube has the gas discharge tube electrically connected between the center conductor and the outer conductor, so that, as with the spark gap, when a signal surges through the protective device, the increased potential difference between the center conductor and the outer conductor ionizes the air in the gas discharge tube, creating a path for the electricity from the center conductor to flow through the gas discharge tube to the outer conductor, and to ground. Gas tube devices have limited lifetimes before the gas tube devices start leaking electrical current.

A quarter wave stub is a section of conductive line that has a length one quarter of the wavelength of waves with a frequency at the center of the desired frequency bandwidth being transmitted. The quarter wave stub can be used as a notch filter to attenuate certain frequencies outside a certain bandwidth. A protective device with a quarter wave stub has the stub extending from the center conductor to or through the outer conductor. The stub acts as a short circuit from the center conductor to the outer conductor outside the notched frequency bandwidth. Quarter wave stub devices have a relatively limited bandwidth capability.

Establishing dielectric gaps in the signal path of the center conductor has been disclosed for use in quarter wave stub surge protectors. See U.S. Pat. No. 8,134,818. Surge protectors such as those direct the undesired signals to ground through the outer conductor.

The quarter wave stub, as well as the gas tube devices and spark gap devices, that provide an electrical path from the center conductor to the outer conductor also provide an electrical connection from the outer conductor to the center conductor. Therefore, undesirable signals can be transmitted in the reverse direction from what is desired with these devices, and in this manner, undesirable signals can be introduced onto the center conductor through the protective device.

It would be advantageous to provide a coaxial cable protective device without the disadvantages of the protective devices described above.

### SUMMARY

A protective device for a coaxial cable system comprising a first interface pin defining a longitudinal axis, the first interface pin having a first end, a second interface pin having a second end, the second interface pin positioned in axial relationship to the first interface pin such that a dielectric gap is formed between the first end and the second end, the dielectric gap configured to couple radio frequency signals across the dielectric gap and block low frequency electrical current across the dielectric gap, a housing disposed in surrounding axial relation to the first interface pin, the housing having a first coupling end, and an outer conductor interface having a second coupling end, the outer conductor interface positioned in axial relationship to the housing such that a coupling gap is formed between the first coupling end and the second coupling end, the coupling gap configured to couple radio frequency signals across the coupling gap and block low frequency electrical current across the coupling gap.

A method for conducting radio frequency signals over a coupling path while blocking low frequency electrical current, the method comprising the steps of placing a first interface pin defining a longitudinal axis, the first interface pin having a first end in axial relationship to a second interface pin having a second end to form a dielectric gap between the first end and the second end, positioning a housing having a first coupling end in surrounding axial relation to the first interface pin, placing the housing in axial relationship to an outer conductor interface having a second coupling end to form a coupling gap between the first coupling end and the second coupling end, forming a first capacitor element by (a) sizing the dielectric gap, and (b) selecting a first spacer for disposition within the dielectric gap, the capacitor element adapted to (a) couple radio frequency signals and (b) block low frequency electrical current between the first and second connection elements, and forming a second capacitor element by (a) sizing the coupling gap, and (b) selecting a second spacer for disposition within the coupling gap, the capacitor element adapted to (a) couple radio frequency signals and (b) block low frequency electrical current between the first and second connection elements.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of invention. Thus, for further understanding of the invention, reference can be made to the following detailed description, read in connection with the drawings in which:

FIG. 1 depicts a cutaway perspective view of one embodiment of a protective device;

FIG. 2 depicts a detail view of the coupling between the first interface pin and the second interface pin shown in FIG. 1;

FIG. 3 depicts a detail view of the coupling between the housing and the outer conductor interface shown in FIGS. 1; and

FIG. 4 depicts a cutaway perspective view of another embodiment of a protective device.

### DETAILED DESCRIPTION

Passing a surge to ground through the outer conductor works under the assumption of a properly grounded outer conductor. Also, the effect of sending the surge to ground merely suppresses the signal which may be in direct radio contact at a cellular transmission tower or other sensitive coaxial cable device. Creating dielectric gaps within the conductive paths of both the center conductor and the outer conductor in a coaxial cable system provide an effective surge blocker, blocking even the voltage of the surge. The dielectric gaps and spaces can be tuned to a specified axial and radial length to pass signals of a desired frequency and block lower frequency signals, such as those resulting from a lightning strike, thus avoiding the disadvantages of the state of the art surge protection devices. Furthermore, the signal blocking ability of the capacitive couples does not degrade with use or over time.

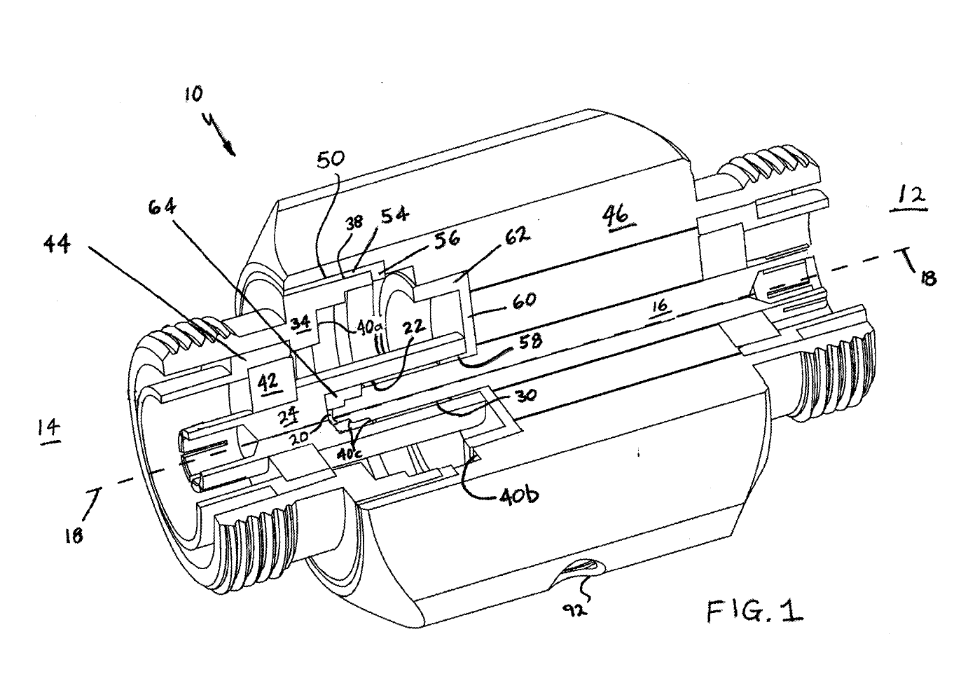

FIG. 1 depicts a cutaway perspective view of one embodiment of a protective device 10. The protective device 10 has a first interface 12, a second interface 14, and a housing 46. The interfaces 12, 14 are configured to mate with coaxial cable connector and device interfaces. In the illustrated example, the interfaces 12, 14 are female 7/16 DIN-type adapted to receive a male 7/16 DIN-type coaxial cable connector interface. Each interface 12, 14 may instead be selected from the group of interface styles consisting of, for example, BNC, TNC, F-type, RCA-type, 7/16 DIN male, 7/16 DIN female, N-male, N-female, SMA male, and SMA female.

The first interface 12 of the protective device 10 includes a first interface pin 16 having a longitudinal axis 18. The first interface pin 16 includes a plug end 30. The plug end 30 is shown as a cylindrical protrusion. The second interface 14 includes a second interface pin 24. The second interface pin 24 includes a socket end 22. The socket end 22 is depicted as comprising a cylindrical internal cavity. The socket end 22 is configured to receive the plug end 30 of the first interface pin 16 in such a way that when aligned on a common axis 18, there exists a dielectric gap 32. In the alternative, the first interface pin 16 may have a socket end and the second interface pin 24 may have a plug end. Other variations of the interface pins can also exist that create a capacitive coupling between the first interface pin 16 and the second interface pin 24. For example, the plug end 30 and the socket end 22 may have an elliptical or rectangular cross-section, so long as the mated pair results in the desired radial gap, or dielectric gap 32.

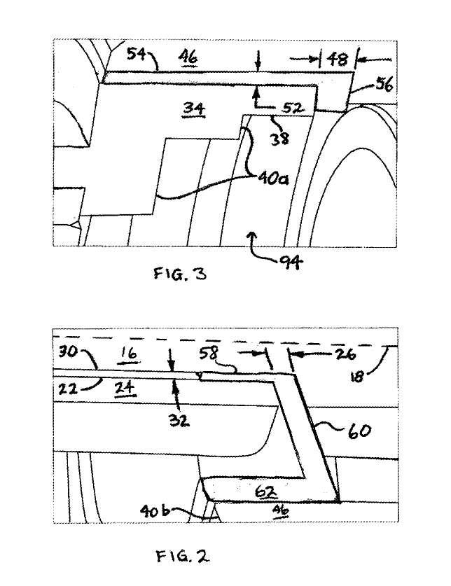

With further reference to the figures, FIG. 2 depicts a detail view of the coupling between the first interface pin 16 and the second interface pin 24. When the first interface pin 16 mates with the second interface pin 24 in coaxial alignment with the longitudinal axis 18, a dielectric gap 32 exists radially between the plug end 30 and the socket end 22. To further isolate the first interface pin 16 from the second interface pin 24, the illustrated assembly provides a dielectric space 26 located axially between the first interface pin 16 and the socket end 22 of the second interface pin 24. Still further, an interface pin spacer 64, having dielectric properties, extends circumferentially over a portion of the plug end 30 of the first interface pin 16.

The dielectric gap 32 may be maintained by a first spacer 58 that fits within the dielectric gap 32. In the disclosed embodiment, the first spacer 58 is a cylindrical sleeve that does not occupy the entire length of the dielectric gap 32. An electrical insulator may occupy the center dielectric space 26. In the disclosed embodiment, the first spacer 58 is adapted to occupy both the dielectric gap 32 and the dielectric space 26. Thus, the first spacer 58 further includes a radial leg 60.

The dielectric gap 32 may also be maintained by a support structure 42 configured to place the second interface pin 24 in coaxial relation to components making up the second interface 14. In the illustrated embodiment, the support structure 42 locates the second interface pin 24 coaxially within a guide sleeve 44 and an outer conductor interface 34. The support structure 42 includes a bore centrally disposed therethrough for receiving the second interface pin 24. The support structure 42 may be fabricated from a non-conducting material, such as plastic. In the disclosed embodiment the support structure 42 is a washer, but other configurations are possible. For example, the support structure 42 may comprise an inner ring, an outer ring, and support arms joining the inner ring to the outer ring. Further, the inner ring and outer ring may be solid or segmented.

The first spacer 58 may comprise a dielectric material. In one example, the dielectric material is solid. Examples of solid dielectrics include ceramic, mica, glass, plastics, and the oxides of various metals. Some liquids and gases can serve as good dielectric materials. Thus, in some embodiments, the first spacer 58 may be distilled water, or air. The first spacer 58 may also comprise a vacuum. Further, the first spacer 58 may comprise a radio wave absorptive material.

With further reference to the figures, FIG. 3 depicts a detail view of the coupling between the housing 46 and the outer conductor interface 34. In the illustrated embodiment, the housing 46 of the protective device 10 is integral with the first interface end 12. In other embodiments, the housing 46 is not integral with the first interface end 12 or the housing is electrically coupled to the first interface end 12. The housing 46 is in surrounding axial relationship with and is electrically isolated from the interface pins 16, 24 sufficient for a 50-Ohm or 75-Ohm coaxial cable system, depending on the application. The housing 46 has a first housing end 50. The first housing end 50 includes an internal cavity configured to receive a first interface plug 38 of the outer conductor interface 34. The first interface plug 38 extends over a portion of the outer conductor interface 34 from one end. The outer conductor interface 34 may be rigid, as shown, or alternatively may include a flexible metal sheath surrounded by a protective outer jacket.

When the outer conductor interface 34 mates with the housing 46 in coaxial alignment with the longitudinal axis 18, a coupling gap 52 exists radially between the first interface plug 38 and the first housing end 50. To further isolate the housing 46 from the outer conductor interface 34, the illustrated assembly provides an axial space 48 located axially between the first interface plug 38 and the housing 46. The coupling gap 52 may be maintained by a second spacer 54 that fits within the coupling gap 52. In the disclosed embodiment, the second spacer 54 is a cylindrical sleeve having a lip, or flanged portion, 56. The flanged portion 56 maintains, or fills, the axial space 48. In some embodiments, the flanged portion 56 may be a separate piece. For example, the second spacer 54 may not extend the entire axial length of the coupling gap 52. An electrical insulator may occupy the axial space 48. In the disclosed embodiment, the second spacer 54 is adapted to occupy both the coupling gap 52 and the axial space 48.

The second spacer 54 may comprise a dielectric material. In one example, the dielectric material is solid. Examples of solid dielectrics include ceramic, mica, glass, plastics, and the oxides of various metals. Some liquids and gases can serve as good dielectric materials. Thus, in some embodiments, the second spacer 54 may be distilled water, or air. The second spacer 54 may also comprise a vacuum. Further, the second spacer 54 may comprise a radio wave absorptive material.

The coupling gap 52 may also be maintained by the first spacer 58 configured to place the housing 46 in coaxial relation to the outer conductor interface 34. In the illustrated embodiment, the first spacer 58 includes a radial leg 60 and an outer lip 62. The radial leg 60 extends a radial length making contact with the housing 46. The outer lip 62 extends axially from the free end of the radial leg 60 toward the second interface 14 to form a supporting surface for the housing 46. In another embodiment, the outer lip 62 may extend toward the first interface end 14. In yet another embodiment, the outer lip 62 and the radial leg 60 are not integral with the first spacer 58. The outer lip 62 and the radial leg 60 may provide a positioning and support function for the first interface pin 24.

In order to conduct electromagnetic signals in the RF range through the protective device 10, the first interface pin 16, second interface pin 24, dielectric gap 32, and first spacer 58 may be configured as a capacitor, i.e. two conductors separated a specified distance by an insulator. Similarly, the outer conductor interface 34, housing 46, axial space 48, and second spacer 54 may be configured as a capacitor.

A group of components acting as a capacitor will pass alternating signals from one conductor across the insulator to the other conductor by capacitive coupling. In a coaxial cable system, capacitive coupling between the center conductor and the outer conductor is minimized by distance such that resistance is the dominant force. The inventor of the present disclosure has determined that a properly configured capacitor within each conductive path will pass alternating signals such as those in the radio frequency, RF, band, and block steady or low frequency electrical signals such as those generated in a lightning strike. RF signals may then be conducted through the protective device 10 using capacitive coupling, while DC current and low frequency signals are blocked by the capacitors. Dielectric spacers 54, 56, 58, 60, 64 are positioned in the dielectric gap 32, coupling gap 52, and dielectric spaces 26, 48, 20 to support and maintain certain spacing, as well as to insulate between the adjacent sections of the protective device 10.

The dielectric gap 32, coupling gap 52, and dielectric spaces 26, 48, 20 and the corresponding dielectric spacers 54, 56, 58, 60, 64 may be shaped according to the desired blocking and passing characteristics of the protective device 10. Particularly, the capacitance values of the capacitive coupling in the signal paths may be tuned for passing desired frequency levels. For example, the axial lengths of the mated plugs 30, 38 and socket end 22 may be selected for a particular capacitance to block specified frequencies. Also, the axial distance of the dielectric spaces 26, 48, 20 may be selected for a particular capacitance to block specified frequencies.

Still referring to the example illustrated by FIGS. 1-3, the coupling gap 52 and the axial space 48 separating the housing 46 from the outer conductor interface 34 may have the unintended effect of increasing the egress, or leakage, of energy out of the protective device 10, which could decrease performance in the RF range. The leakage may be attenuated by adding a radiation-reflective surface on one or more internal surfaces within the protective device 10. The radiation-reflective surface disrupts the propagation of electromagnetic waves along the longitudinal axis 18. This will reduce or eliminate line-of-sight radiation egress. In one example, the radiation-reflective surface may comprise a labyrinthine or stepped structure. In the disclosed embodiment, radiation-reflective surfaces 40a, 40b, and 40c are included on the internal surfaces of the outer conductor interface 34, the housing 46, and the first interface pin 16, respectively. The number of steps and the dimension of the steps in the radiation-reflective surfaces 40a, 40b, and 40c may vary.

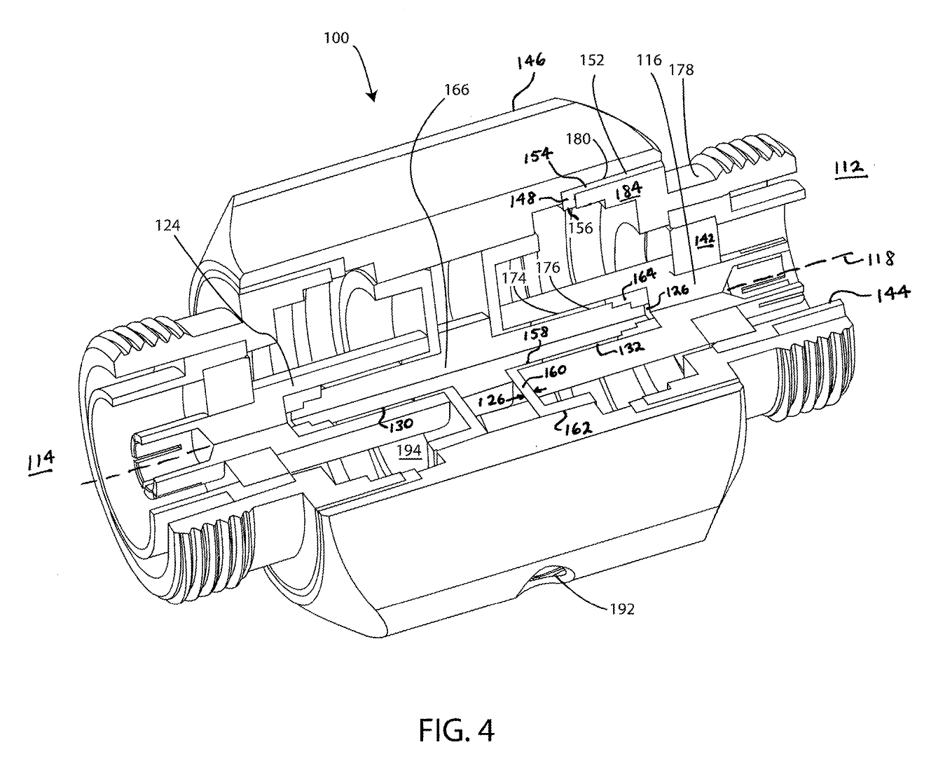

FIG. 4 depicts a cutaway perspective view of another embodiment of a protective device 110. It has been determined that multiple capacitive couplers in a coaxial cable system block a given surge better than a single capacitive coupler. The embodiment represented in FIG. 4 is a dual coupler system, that is, the same arrangement to set up capacitance in the protective device 10 described above at the second interface 14 is mirrored to the first interface 12. In order to achieve this dual coupler system, a coupling pin 166 is introduced to the protective device 110. The coupling pin 166 is shown as a cylindrical member having a longitudinal axis 118. The coupling pin 166 has a first coupling plug 176 and a second coupling plug 130. The second coupling plug 130 corresponds to the plug end 30 of the first interface pin 16 described above. The two plug ends 176, 130 are located on opposing ends of the coupling pin 166. In that way, the first interface 112 may include a first interface pin 116 having a second socket end 174 configured to mate with the first coupling plug 176. In the alternative, the coupling pin 166 may have first and second socket ends and the first interface pin 116 may have a plug end. Other variations of the mating interface can also exist that create a capacitive coupling between the coupling pin 166 and the first interface pin 116.

In the same way that capacitive couplers are set up at the second interface pin 24 and at the outer conductor interface 34, capacitive couplers are set up at the first interface pin 116 and the second outer conductor interface 178. That is to say, when the second socket end 174 of the first interface pin 116 mates with the first coupling plug 176 in coaxial alignment with the longitudinal axis 118, a dielectric gap 132 exists radially between the first coupling plug 176 and the second socket end 174. To further isolate the first interface pin 116 from the coupling pin 166, the illustrated assembly provides a dielectric space 126 located axially between the second socket end 174 and the first coupling plug 176 of the coupling pin 166. Still further, an interface pin spacer 164, having dielectric properties, extends circumferentially over a portion of the first coupling plug 176.

The dielectric gap 132 may be maintained by a first spacer 158 that fits within the dielectric gap 132. In the disclosed embodiment, the first spacer 158 is a cylindrical sleeve that does not occupy the entire length of the dielectric gap 132. An electrical insulator may occupy the center dielectric space 126. In the disclosed embodiment, the first spacer 158 is adapted to occupy both the dielectric gap 132 and the dielectric space 126. Thus, the first spacer 158 further includes a radial leg 160.

The dielectric gap 132 may also be maintained by a support structure 142 configured to place the first interface pin 116 in coaxial relation to components making up the first interface 112. In the illustrated embodiment, the support structure 142 locates the first interface pin 116 coaxially within a guide sleeve 144 and a second outer conductor interface 178. The support structure 142 includes a bore centrally disposed therethrough for receiving the first interface pin 116. The support structure 142 may be fabricated from a non-conducting material, such as plastic. In the disclosed embodiment the support structure 142 is a washer, but other configurations are possible. For example, the support structure 142 may comprise an inner ring, an outer ring, and support arms joining the inner ring to the outer ring. Further, the inner ring and outer ring may be solid or segmented.

The first spacer 158 may comprise a dielectric material. In one example, the dielectric material is solid. Examples of solid dielectrics include ceramic, mica, glass, plastics, and the oxides of various metals. Some liquids and gases can serve as good dielectric materials. Thus, in some embodiments, the first spacer 158 may be distilled water, or air. The first spacer 158 may also comprise a vacuum. Further, the first spacer 158 may comprise a radio wave absorptive material.

With further reference to the Figures, the housing 146 has a second housing end 180. The second housing end 180 comprises an internal cavity configured to receive a second interface plug 184 of the second outer conductor interface 178. The second outer conductor interface 178 may be rigid, as shown, or alternatively may include a flexible metal sheath surrounded by a protective outer jacket.

When the second outer conductor interface 178 mates with the housing 146 in coaxial alignment with the longitudinal axis 118, a coupling gap 152 exists radially between the second interface plug 184 of the second outer conductor interface 178 and the second housing end 180. To further isolate the housing 146 from the second outer conductor interface 178, the illustrated assembly provides an axial space 148 located axially between the second interface plug 184 and the housing 146. The coupling gap 152 may be maintained by a second spacer 154 that fits within the coupling gap 152. In the disclosed embodiment, the second spacer 154 is a cylindrical sleeve having a lip, or flanged portion, 156. The flanged portion 156 maintains, or fills, the axial space 148. In some embodiments, the flanged portion 156 may be a separate piece. For example, the second spacer 154 may not extend the entire axial length of the coupling gap 152. An electrical insulator may occupy the axial space 148. In the disclosed embodiment, the second spacer 154 is adapted to occupy both the coupling gap 152 and the axial space 148.

The second spacer 154 may comprise a dielectric material. In one example, the dielectric material is solid. Examples of solid dielectrics include ceramic, mica, glass, plastics, and the oxides of various metals. Some liquids and gases can serve as good dielectric materials. Thus, in some embodiments, the second spacer 154 may be distilled water, or air. The second spacer 154 may also comprise a vacuum. Further, the second spacer 154 may comprise a radio wave absorptive material.

The coupling gap 152 may also be maintained by the first spacer 158 configured to place the housing 146 in coaxial relation to the second outer conductor interface 178. In the illustrated embodiment, the first spacer 158 includes a radial leg 160 and an outer lip 162. The radial leg 160 extends a radial length making contact with the housing 146. The outer lip 162 extends axially from the free end of the radial leg 160 toward the first interface 112 to form a supporting surface for the housing 146. In another embodiment, the outer lip 162 may extend toward the second interface end 114. In yet another embodiment, the outer lip 162 and the radial leg 160 are not integral with the first spacer 158. The outer lip 162 and the radial leg 160 may provide a positioning and support function for the coupling pin 166.

Doubling or otherwise increasing the number of capacitive couples, such as shown symmetrically in the embodiment illustrated by FIG. 4, increases the ability to manipulate the electrical characteristics, in addition to increasing the signal blocking capacity.

The housing 46, 146 has a grounding port 92, 192 to which a grounding wire, grounding cable, or other grounding conductor can be connected. Any undesirable signals that pass across the coupling gaps 52, 152 will pass to the grounding conductor to the grounding port 92, 192 because the grounding conductor has a low resistance relative to the resistance of the housing 46, 146 and the interface pins 16, 24, 116, 124.

The interface pins 24, 116, 124 are isolated from the outer conductor interfaces 34, 134, 178 in part by a device cavities 94, 194. The device cavity 94, 194 can be separated into a plurality of segments by the dielectric spacers such as first spacer 58, 158. The physical dimensions and characteristics of the device cavity 94, 194 may be manipulated to produce desirable signal characteristics. For example, it may be desirable to balance the impedance of the protective device 10, 110 or match the impedance of the protective device 10, 110 with the impedance of the coaxial cable system to which the protective device 10, 110 is connected. The device cavity 94, 194 may be modified to a target impedance. As another example, the device cavity 94, 194 may be modified to alter the frequency bandwidth of signals passed through the center conductor.

While the present invention has been described with reference to a number of specific embodiments, it will be understood that the true scope of the invention should be determined only with respect to claims that can be supported by the present specification. Further, while in numerous cases where systems and apparatuses and methods are described as having a certain number of elements it will be understood that such systems, apparatuses and methods can be practiced with fewer than the mentioned certain number of elements. Also, while a number of particular embodiments have been described, it will be understood that features and aspects that have been described with reference to each particular embodiment can be used with each remaining particularly described embodiment.

We claim:

1. A protective device for a coaxial cable system comprising:
a first interface pin defining a longitudinal axis, the first interface pin having a first end;
a second interface pin having a second end, the second interface pin positioned in axial relationship to the first interface pin such that a dielectric gap is formed between the first end and the second end, the dielectric gap configured to couple radio frequency signals across the dielectric gap and block low frequency electrical current across the dielectric gap;
a housing disposed in surrounding axial relation to the first interface pin, the housing having a first coupling end; and
an outer conductor interface having a second coupling end, the outer conductor interface positioned in axial relationship to the housing such that a coupling gap is formed between the first coupling end and the second coupling end, the coupling gap configured to couple radio frequency signals across the coupling gap and block low frequency electrical current across the coupling gap.

2. The protective device of claim 1, wherein in the first end includes a cylindrical protrusion sharing the longitudinal axis and the second end includes a cylindrical internal cavity sized to receive the first end.

3. The protective device of claim 2, wherein the dielectric gap defines a radial distance between the mated first end and the second end.

4. The protective device of claim 3, further including a dielectric space located along the longitudinal axis, the dielectric space formed between the mated first end and second end.

5. The protective device of claim 1, further including a first spacer configured to fit within the dielectric gap

6. The protective device of claim 5, wherein the first spacer comprises a dielectric material.

7. The protective device of claim 6, where the dielectric material is ceramic.

8. The protective device of claim 6, wherein the first spacer is configured to fill the dielectric gap.

9. The protective device of claim 5, wherein the first spacer extends from the first interface pin to the housing to locate the first interface pin with respect to the housing.

10. The protective device of claim 5, wherein the first spacer is comprised of a radio wave absorptive material.

11. The protective device of claim 1, further including a second spacer configured to fit within the coupling gap.

12. The protective device of claim 1, further including a radiation-reflective surface located on one of the housing, the outer conductor interface, the first interface pin, or the second interface pin to disrupt propagation of electromagnetic waves along the longitudinal axis.

13. The protective device of claim 12, wherein the radiation-reflective surface comprises a step.

14. The protective device of claim 12, wherein the radiation-reflective surface is an end face.

15. The protective device of claim 1, further including a grounding port to enable attachment of a grounding conductor.

16. A method for conducting radio frequency signals over a coupling path while blocking low frequency electrical current, the method comprising the steps of:
placing a first interface pin defining a longitudinal axis, the first interface pin having a first end in axial relationship to a second interface pin having a second end to form a dielectric gap between the first end and the second end;
positioning a housing having a first coupling end in surrounding axial relation to the first interface pin;
placing the housing in axial relationship to an outer conductor interface having a second coupling end to form a coupling gap between the first coupling end and the second coupling end;
forming a first capacitor element by (a) sizing the dielectric gap, and (b) selecting a first spacer for disposition within the dielectric gap, the capacitor element adapted to (a) couple radio frequency signals and (b) block low frequency electrical current between the first and second connection elements; and
forming a second capacitor element by (a) sizing the coupling gap, and (b) selecting a second spacer for disposition within the coupling gap, the capacitor element adapted to (a) couple radio frequency signals and (b) block low frequency electrical current between the first and second connection elements.

17. The method of claim 16, wherein the first end includes a cylindrical feature sharing the longitudinal axis and the second end includes a cylindrical internal cavity sized to receive the first end.

18. The method of claim 16, wherein one of the housing, the outer conductor interface, the first interface pin, or the second interface pin includes a radiation-reflective surface to disrupt propagation of electromagnetic waves along the longitudinal axis

19. The method of claim 18, wherein the radiation-reflective surface comprises a step.

20. The method of claim 16, further including the step of attaching a grounding conductor to a grounding port in electrical contact with the housing.
